(19) United States
(12) Patent Application Publication
(10) Pub. No.: US 2013/0161661 A1
(43) Pub. Date: Jun. 27, 2013

(54) CIRCUIT BOARD, DISPLAY MODULE, AND ELECTRONIC APPARATUS

(71) Applicant: Sony Corporation, Tokyo (JP)

(72) Inventors: Keiichi Akamatsu, Kanagawa (JP); Yuichi Kato, Kanagawa (JP); Kenta Masuda, Kanagawa (JP)

(73) Assignee: SONY CORPORATION, Tokyo (JP)

(21) Appl. No.: 13/711,301

(22) Filed: Dec. 11, 2012

(30) Foreign Application Priority Data
Dec. 22, 2011 (JP) 2011-281213

(51) Int. Cl. H01L 27/15

(52) U.S. Cl. CPC H01L 27/15
USPC 257/88; 361/783; 361/749

(57) ABSTRACT

A circuit board includes: a first substrate provided with a device section, the device section including one or a plurality of active devices; a plurality of first wiring layers each extending from the device section toward a periphery of the first substrate; and a plurality of second substrates each opposed to and bonded to the first wiring layer at the periphery of the first substrate and each having a second wiring layer, the second wiring layer being electrically connected to each of the first wiring layers. The first substrate has a cutout in one or more regions each facing one of the plurality of second substrates.

### CROSS REFERENCES TO RELATED APPLICATIONS

The present application claims priority to Japanese Priority Patent Application JP 2011-281213 filed in the Japan Patent Office on Dec. 22, 2011, the entire content of which is hereby incorporated by reference.

### BACKGROUND

The present disclosure relates to a circuit board connected with a print board on which electronic components such as integrated circuits are mounted, and to a display module and an electronic apparatus that use the circuit board.

In recent years, along with the popularization of mobile phones, electronic papers, and the like, in a display, a method of bonding a display section (a display panel) to a driving section therefor (a driver, a circuit, and the like) with use of a flexible printed circuit board (hereinafter, referred to as an FPC) has been employed. The FPC is a printed circuit board including metal electrodes which are each made of copper or the like on a flexible base material such as polyimide and polyester.

At the time of bonding, wirings drawn from the display section are bonded to the metal electrodes formed on the FPC with use of an anisotropic conductive film and the like. However, the wirings and the metal electrodes are each formed in a fine pattern, and thus displacement, bonding failure, and the like may occur in bonding.

In such a case, the FPC is physically detached using a solvent or a spatula, is then cleaned to restore the state before mounting, and is mounted again in many cases. For example, in Japanese Unexamined Patent Application Publication No. 2010-232277, a repair technique is disclosed in which the FPC is mechanically detached and is mounted again.

### SUMMARY

In the technique of Japanese Unexamined Patent Application Publication No. 2010-232277, however, since the FPC is mechanically detached, it is concerned that the yield may be decreased. Therefore, it is desirable that wiring connection be achieved in more simple processes and yield be improved, at the time of mounting the FPC and the like on a display panel.

It is desirable to provide a circuit board, a display module, and an electronic apparatus that are capable of improving yield in simple mounting processes.

According to an embodiment of the disclosure, there is provided a circuit board including: a first substrate provided with a device section, the device section including one or a plurality of active devices; a plurality of first wiring layers each extending from the device section toward a periphery of the first substrate; and a plurality of second substrates each opposed to and bonded to the first wiring layer at the periphery of the first substrate and each having a second wiring layer, the second wiring layer being electrically connected to each of the first wiring layers. The first substrate has a cutout in one or more regions each facing one of the plurality of second substrates.

According to an embodiment of the disclosure, there is provided a display module including: a first substrate including a device section and a display section, the device section including one or a plurality of active devices, the display section including a plurality of pixels; a plurality of first wiring layers each extending from the device section toward a periphery of the first substrate; and a plurality of second substrates each opposed to and bonded to the first wiring layer in the periphery of the first substrate and each having a second wiring layer, the second wiring layer being electrically connected to each of the first wiring layers. The first substrate has a cutout in one or more regions each facing one of the plurality of second substrates.

In the circuit board and the display module of the embodiments of the disclosure, the plurality of first wiring layers extending from the device section toward the periphery of the first substrate is provided on the first substrate, and the second substrate having the second wiring layer is bonded to each of the first wiring layers in the periphery of the first substrate. The first substrate has the cutout in a region facing one or more of the second substrates. In the mounting process, even when connection failure occurs due to influence of displacement and the like, the portion where the connection failure occurs is locally cut off (the cutout is formed), and then the rebonding (repair mounting) is performed. Therefore, it is possible to suppress damage of the first wiring layer in simple processes, and to achieve favorable wiring connection.

According to an embodiment of the disclosure, there is provided an electronic apparatus with a display module. The display module includes: a first substrate including a device section and a display section, the device section including one or a plurality of active devices, the display section including a plurality of pixels; a plurality of first wiring layers each extending from the device section toward a periphery of the first substrate; and a plurality of second substrates each opposed to and bonded to the first wiring layer in the periphery of the first substrate, and each having a second wiring layer, the second wiring layer being electrically connected to each of the first wiring layers. The first substrate has a cutout in one or more regions each facing one of the plurality of second substrates.

According to the circuit board and the display module of the embodiments of the disclosure, the first wiring layer extending from the device section toward the periphery of the first substrate is provided on the first substrate, and the second substrate having the second wiring layer electrically connected to the first wiring layer is opposed to and bonded to the first wiring layer in the periphery of the first substrate. The first substrate has the cutout in a region facing one or more of the second substrates, and thus it is possible to suppress damage of the first wiring layer and to perform repair mounting. Consequently, it is possible to improve yield in simple mounting processes.

It is to be understood that both the foregoing general description and the following detailed description are exemplary, and are intended to provide further explanation of the technology as claimed.

Additional features and advantages are described herein, and will be apparent from the following Detailed Description and the figures.

### BRIEF DESCRIPTION OF THE FIGURES

The accompanying drawings are included to provide a further understanding of the disclosure, and are incorporated in and constitute a part of this specification. The drawings illustrate embodiments and, together with the specification, serve to explain the principles of the technology.

FIG. 1 is a plan schematic diagram illustrating a configuration of a display module according to an embodiment of the disclosure.

FIG. 2 is a schematic diagram for explaining a detailed configuration of bonding portions illustrated in FIG. 1.

FIG. 3 is a schematic diagram illustrating a configuration in the vicinity of one of the bonding portions illustrated in FIG. 2.

FIGS. 4A and 4B are schematic diagrams for explaining a detailed configuration of the bonding portion illustrated in FIG. 3.

FIG. 5 is a schematic diagram illustrating a configuration in the vicinity of the other bonding portion (repair mounting) illustrated in FIG. 2.

FIG. 6 is a schematic diagram for explaining a detailed configuration of the bonding portion illustrated in FIG. 5.

FIGS. 7A and 7B are schematic diagrams for explaining a method of mounting an FPC (two-stage mounting) in a process order.

FIGS. 8A and 8B are schematic diagrams illustrating processes following the process of FIG. 7B.

FIGS. 9A and 9B are schematic diagrams for explaining a mounting method according to a comparative example 1.

FIGS. 10A and 10B are schematic diagrams for explaining a mounting method according to a comparative example 2.

FIG. 11 is a schematic diagram illustrating an example of arrangement of a plurality of bonding portions.

FIG. 12 is a schematic diagram illustrating an arrangement example of bonding portions and cutouts according to a modification 1.

FIGS. 13A to 13C are schematic diagrams each illustrating a shape of a cutout according to a modification 2.

FIG. 14 is a schematic diagram illustrating a configuration of a periphery of a substrate which allows a mounting method (three-stage mounting) according to a modification 3.

FIG. 15 is a schematic diagram illustrating an example of an arrangement of bonding portions formed by the mounting method according to the modification 3.

FIG. 16 is a perspective view illustrating an appearance of an application example 1.

FIG. 17A is a perspective view illustrating an appearance of an application example 2 viewed from a front side thereof, and FIG. 17B is a perspective view illustrating the appearance viewed from a back side thereof.

FIG. 18 is a perspective view illustrating an appearance of an application example 3.

FIG. 19 is a perspective view illustrating an appearance of an application example 4.

FIG. 20A is a front view of an application example 5 in an open state, FIG. 20B is a side view thereof, FIG. 20C is a front view of the application example 5 in a closed state, FIG. 20D is a left side view thereof, FIG. 20E is a right side view thereof, FIG. 20F is a top view thereof, and FIG. 20G is a bottom view thereof.

FIGS. 21A and 21B are perspective views each illustrating an appearance of an application example 6.

### DETAILED DESCRIPTION

Hereinafter, a preferred embodiment of the disclosure will be described in detail with reference to drawings. Note that the description will be given in the following order.
1. Embodiment (an example of a display module in which a plurality of FPCs are bonded to a periphery of a substrate and cutouts are provided in parts of bonding portions)
2. Modification 1 (other examples of a shape of a cutout)
3. Modification 2 (an example in which one cutout is provided to correspond to a plurality of bonding portions)
4. Modification 3 (an example in a case of performing three-stage mounting)
5. Application Examples (examples of an electronic apparatus)

[Embodiment]

[Configuration]

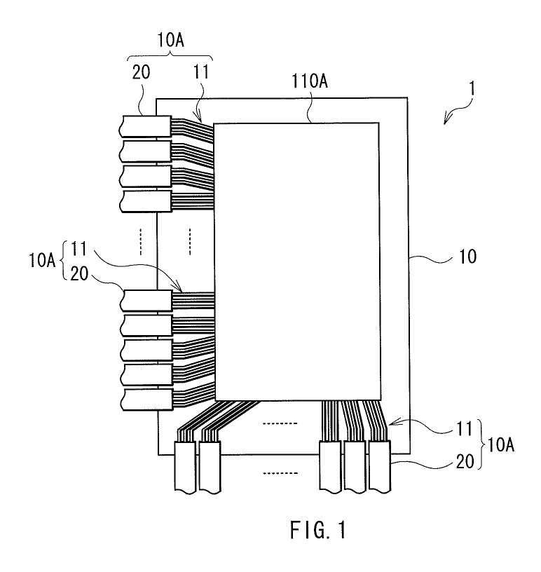

FIG. 1 schematically illustrates a configuration of a display module (a display module 1) according to an embodiment of the disclosure. The display module 1 is configured by bonding (connecting, adhering) a plurality of flexible printed circuit board (hereinafter, referred to as FPCs) 20 on a part of a substrate 10. Note that the substrate 10 corresponds to a specific example of “a first substrate” of the disclosure and the FPC 20 corresponds to a specific example of “a second substrate” of the disclosure. In addition, the configuration (the substrate 10, a device section, and a bonding portion 10A) of the display module 1 except for a display section 110A described later corresponds to a specific example of a “circuit board” of the disclosure.

The substrate 10 is formed of a flexible plastic sheet such as polyimide (PI), polyethylene terephthalate (PET), polyether sulfone (PES), polyethylene naphthalate (PEN), polycarbonate (PC), and a liquid crystal polymer. Alternatively, the substrate 10 is a flexible metal sheet such as stainless steel (SUS), aluminum (Al), and copper (Cu), a surface of which is subjected to insulation treatment. The substrate 10 has a thickness of, for example, 0.015 mm to 1 mm.

The display section 110A is provided on the substrate 10. The display section 110A includes a plurality of pixels each formed of, for example, a liquid crystal display device, an organic electroluminescence device, or an electrophoretic device. The device section (not illustrated) including an active device (a thin film transistor and the like), a capacitor, and the like is provided on the substrate 10 (for example, a back surface of the display section 110A). The active device is intended to drive the display section 110A for each pixel. On the substrate 10, wiring layers 11 are provided to extend from the display section 110A toward the periphery of the substrate 10.

Although the detail will be described later, each of the wiring layer 11 includes a plurality of wirings 11a, and is electrically connected to a wiring (a wiring 21a described later) provided on the FPC 20 on a panel peripheral region. The plurality of wirings 11a is provided to extend from the display section 110A toward the periphery of the substrate 10.

The FPC 20 is a printed circuit board used for mounting a driver IC for pixel drive and the like on the substrate 10 (for connecting to the wiring layer 11), and has flexibility. In the FPC 20, a plurality of wiring layers 21 (not illustrated in FIG. 1) and electronic components (not illustrated) such as integrated circuits, resistors, and capacitors are provided on one surface or both surfaces of an insulating film formed of polyimide, polyester, or the like.

In the embodiment, a plurality of the wiring layers 11 each including the plurality of wirings 11a is provided on the substrate 10, and the FPC 20 is opposed to and bonded to each of the wiring layers 11 (for each wiring layer 11). In other words, the plurality of wirings 11a extending from the display section 110A is segmented per a predetermined number of lines, and each group of segmented wirings 11a is bonded to one FPC 20. Hereinafter, the pair of the wiring layer 11 and the FPC 20 (including the wiring layer 21) is referred to as a bonding portion 10A. In other words, in the embodiment, the electronic components (the drive IC and the like) are mounted on the substrate 10 by the plurality of bonding portions 10A.

The plurality of bonding portions 10A is necessarily provided on at least a part of the periphery of the substrate 10. Herein, the plurality of bonding portions 10A is arranged side by side along adjacent two sides of the rectangular substrate 10. Incidentally, the layout of the bonding portions 10A is not limited thereto, and the bonding portions 10A may be provided on any one side of four sides or on two sides opposing to each other. In addition, the bonding portions 10A may be provided along three or more sides. Furthermore, the number of the bonding portions 10A provided on each side is not specifically limited, and is appropriately set depending on the number, the size, the layout, and the like of the wirings 11A.

In the plurality of bonding portions 10A, FPC rebonding to the substrate 10 (repair mounting) is allowed to be performed in the mounting process. In other words, the bonding portion 10A is designed to achieve multi-stage mounting. The configuration of the bonding portion 10A is described below.

[Detailed Configuration of Bonding Portion 10A]

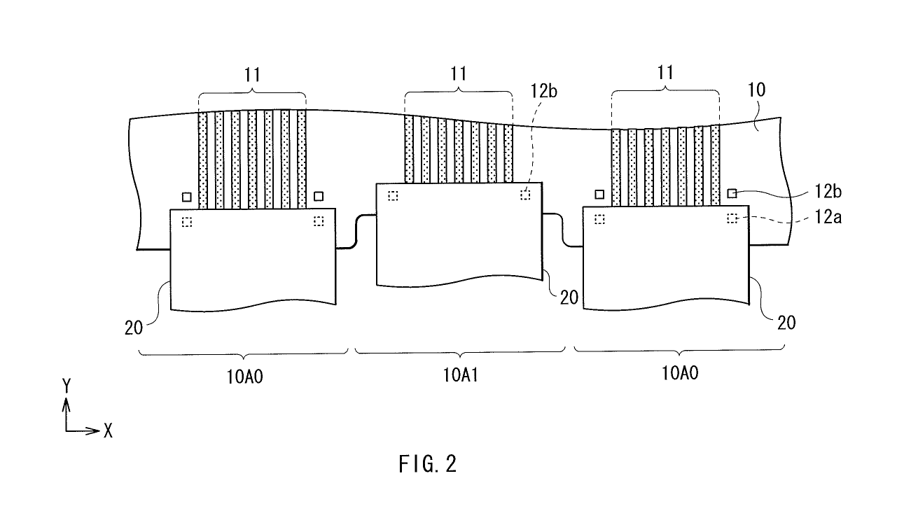

FIG. 2 selectively illustrates a part of the configuration of the periphery of the substrate 10, corresponding to three bonding portions 10A arranged along one side of the substrate 10. Note that, in FIG. 2, the configuration of each of the substrates 10 and the FPCs 20 is illustrated in a simplified manner. As illustrated in FIG. 2, the plurality of bonding portions 10A each correspond to one of two kinds of bonding portions (bonding portions 10A0 and 10A1). The two kinds of bonding portions are different from each other in an alignment position. The bonding portion 10A0 is a portion that has a favorable wiring connection obtained through one FPC bonding process without being subjected to repair mounting. On the other hand, the bonding portion 10A1 is a portion in which FPC bonding is performed through repair mounting. In other words, in the embodiment, the bonding portion 10A0 and the bonding portion 10A1 which is formed through a repair mounting process are mixedly provided. Of them, in the bonding portion 10A0, the FPC 20 is bonded with use of alignment marks 12a described later, and in the bonding portion 10A1, the FPC 20 is bonded with use of alignment marks 12b described later. In other words, a position of the FPC 20 in a Y direction is different between the bonding portions 10A0 and 10A1, and the FPC 20 of the bonding portion 10A1 is bonded closer to the center (inner side) of the substrate 10, compared with the FPC 20 of the bonding portion 10A0.

(Bonding Portion 10A0)

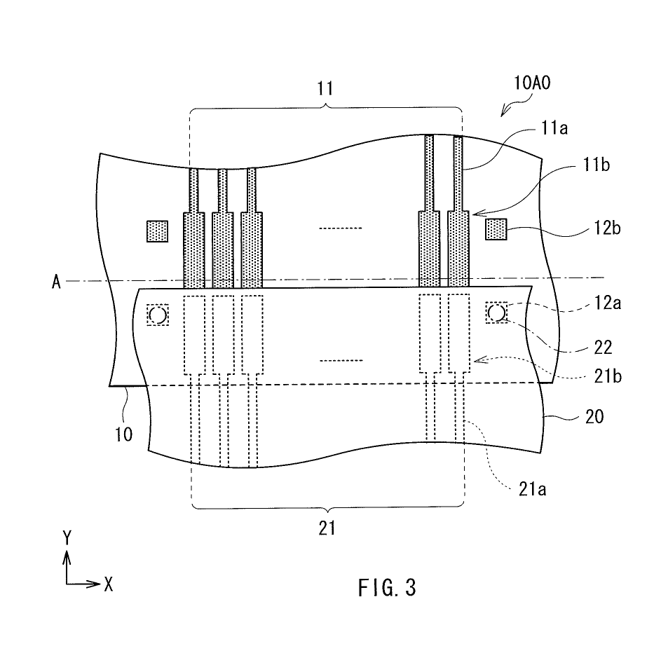

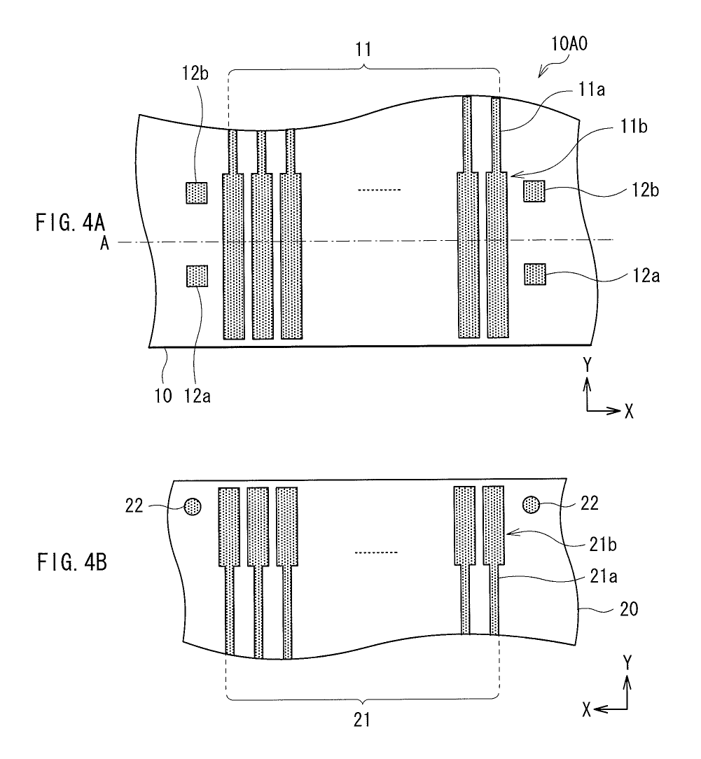

FIG. 3 illustrates a configuration in the vicinity of the bonding portion 10A0 in an enlarged manner. FIGS. 4A and 4B illustrate the bonding portion 10A0 in an exploded manner, where FIG. 4A illustrates a configuration of a main part on the substrate 10, and FIG. 4B illustrates a configuration on a bonding surface side of the FPC 20.

The wiring layer 11 formed on the substrate 10 includes the plurality of wirings 11a as described above, and a connection pad 11b is provided at an end of each of the plurality of wirings 11a. Specifically, one end of each of the wirings 11a is electrically connected to a terminal (for example, a gate, a source, or a drain) of a thin film transistor in the above-described device section on the substrate 10, for example, and other end of each of the wirings 11a is connected to the connection pad 11b at the periphery of the substrate 10. The wiring 11a and the connection pad 11b are each formed of a simple substance or an alloy of aluminum (Al), molybdenum (Mo), chromium (Cr), titanium (Ti), ITO, or the like, and each has a thickness of, for example, 0.1 μm to 2 μm. The wiring 11a and the connection pad 11b may be collectively (integrally) formed of the same material or may be formed of different materials.

On the other hand, in the FPC 20, the wiring layer 21 is provided to face the wiring layer 11 as described above. The wiring layer 21 includes the plurality of wirings 21a and the connection pads 21b each connected to an end of each of the wirings 21a. Specifically, one end (not illustrated) of each of the wirings 21a is electrically connected to an integrated circuit and the like (not illustrated), and the other end (an end on the connection side) thereof is connected to the connection pad 21b. The wiring 21a and the connection pad 21b are each formed of, for example, copper (Cu) or gold (Au), and has a thickness of, for example, 5 μm to 25 μm. The wiring 21a and the connection pad 21b may be collectively formed of the same material or may be formed of different materials.

The wiring layer 11 and the wiring layer 21 are arranged (bonded) to face each other with an adhesive layer (not illustrated) in between. The adhesive layer is formed of an anisotropic conductive adhesive which is a kind of conductive films, and has a thickness of, for example, 25 μm to 30 μm. The anisotropic conductive adhesive is formed by dispersing and mixing conductive particles into an adhesive film, for example. When the anisotropic conductive adhesive is sandwiched between one pair of electrodes and bonded with pressure, conduction is obtainable between the electrodes. The bonding using such an anisotropic conductive adhesive is referred to as ACF bonding, and this ensures electrical connection between the wirings 11a and 21a (in detail, between the connection pads 11b and 21b). The width in the X direction of each of the connection pads 11b and 21b, which are to be bonded, of the wiring layers 11 and 21 is, for example, 50 μm to 250 μm. Note that in consideration of two-stage mounting described later, the width of the connection pad 11b in the Y direction is designed to be larger than that of the connection pad 21b.

As described above, in the bonding portion 10A0, the wirings 11a and 21a in fine scale are connected to each other on a one-to-one basis with the adhesive layer in between. Therefore, in each of the bonding portions 10A0, a plurality of alignment marks (alignment marks 12a, 12b, and 22) for alignment in bonding are formed in each of the substrate 10 and the FPC 20.

(Alignment Marks)

The alignment marks 12a are formed on the substrate 10, and for example, are provided in two positions in total to sandwich the wiring layer 11 (the plurality of connection pads 11b) along the X direction. The alignment marks 12a are formed of, for example, the similar material to that of the wiring layer 11 (the wiring 11a and the connection pad 11b), and are collectively formed in the same process as that of the wiring layer 11, for example. However, the shape, the mount positions, the number, and the like of the alignment marks 12a are not specifically limited, and may be appropriately set depending on the shape of the FPC 20, the wiring layout, and the like.

In the embodiment, although the alignment marks 12a are mainly used in the FPC bonding (a first bonding), the alignment marks 12b are further provided on the substrate 10.

The alignment marks 12b are provided in two positions in total to sandwich the wiring layer 11 on the substrate 10, similarly to the alignment marks 12a, and are collectively formed in the same process as that of the wiring layer 11, for example. The alignment marks 12b are used in repair mounting (a second bonding), and are disposed with a predetermined distance (for example, 1 mm to 5 mm) with respect to the alignment marks 12a in the Y direction. Note that the alignment marks 12b are not used when the repair mounting is unnecessary, and are remained on the substrate 10, as unused alignment marks in a state of not facing the FPC 20, as illustrated in FIG. 3.

As described above, the plurality of alignment marks (herein, two alignment marks 12a and 12b) is formed on the substrate 10 with a predetermined distance toward the inside of the substrate 10. Such a design enables multiple-stage (multiple times) (herein, twice at a maximum) FPC bonding. Although the detail will be described later, in the bonding, the substrate 10 and the FPC 20 are overlaid so that the alignment marks 12a (or 12b) are engaged with the alignment marks 22 on the FPC 20, and thus alignment is performed.

The alignment marks 22 are formed on one surface (herein, a surface on a bonding surface of a panel) of the FPC 20, and are provided in two positions in total to sandwich the wiring layer 21 (the plurality of connection pads 21b) along the X direction. The alignment marks 22 are formed of, for example, the similar material to that of the wiring layer 21 (the wiring 21a and the connection pad 21b), and are collectively formed in the same process as that of the wiring layer 21, for example. Note that the alignment marks 22 may be provided on an opposite surface of the FPC 20 from the substrate 10.

Such alignment marks 22 are formed, before bonding process, in positions where the alignment marks 22 are allowed to be selectively engaged with one of the alignment marks 12a and 12b. Note that, in the bonding portion 10A, in either case where the alignment marks 22 engage with the alignment marks 12a or 12b, the layout of the alignment marks 12a, 12b, and 22, the size of the connection pads 11b and 21b, and the like are designed to allow the connection pads 11b and 21b to face each other. In the bonding portion 10A0, the alignment marks 22 engage with the alignment marks 12a, and thus the wirings 11a and 21a are connected to each other through the connection pads 11b and 21b.

(Bonding Portion 10A1)

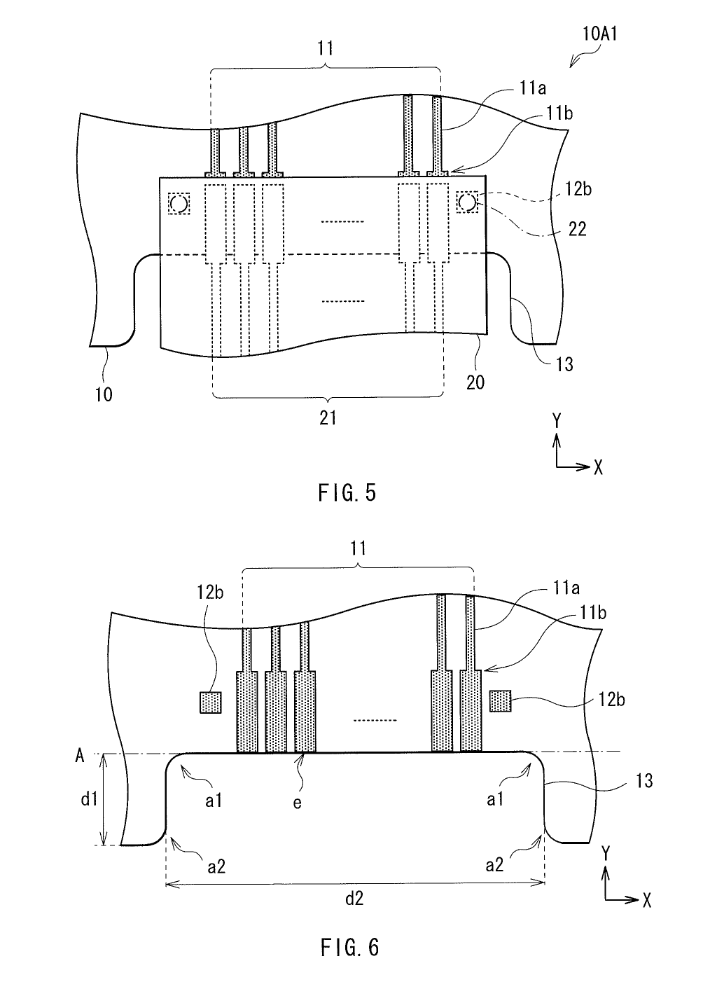

FIG. 5 illustrates a configuration in the vicinity of the bonding portion 10A1 in an enlarged manner. FIG. 6 illustrates a configuration of a main part of the substrate 10 in the bonding portion 10A1. Note that in the bonding portion 10A1, the configuration of the FPC 20 is similar to that of the FPC 20 in the bonding portion 10A0.

In the bonding portion 10A1, a cutout 13 is provided in the periphery of the substrate 10. The cutout 13 is provided in a local region facing the FPC 20, of the substrate 10 in the bonding portion 10A1. In other words, the substrate 10 has the cutout 13 facing one or more of the plurality of FPCs 20.

The cutout 13 is provided to divide the end of the wiring layer 11 (in detail, the plurality of connection pads 11b). The shape (an XY plane shape) of the cutout 13 along the substrate surface is a rectangle including a long side along the X direction, for example. In other words, an end surface e of the connection pad 11b is located at the same position as the long side of the cutout 13.

A width d1 (an upper end position A) of the cutout 13 along the Y direction is set to a width (a position) where the entire bonding portion of the wiring layer 11 and the FPC 20 is allowed to be cut out together with the FPC 20 in the bonding portion 10A0. Moreover, when the FPC is bonded again after formation of the cutout 13, the electrical connection between the connection pads 11b and 21b is necessary to be ensured using the alignment marks 12b. Therefore, the width d1 is set so that an upper end position A of the cutout 13 is located at a predetermined position between the alignment marks 12a and 12b. On the other hand, a width of the cutout 13 along the X direction is set to a width where all of the wirings (the plurality of connection pads 11b) of the wiring layer 11 as described above are allowed to be cut off and the FPCs 20 and the bonding regions are allowed to be separated from the substrate 10. In this example, a region removed by the cutout 13 includes the ends of the connection pads 11b and the alignment marks 12a.

In the cutout 13, at least one portion corresponding to a corner (hereinafter, simply referred to as a corner) of the rectangular shape desirably has a curved shape. Herein, corners a1 and a2 of the rectangular shape each has a curved shape. In other words, the rectangular shape of the cutout 13 is formed by a straight line and a curved line without a bent portion. As will be described later, the cutout 13 is formed by locally cutting the substrate 10 using a mold or the like. Therefore, the cut shape desirably includes as few bent portions as possible because impact resistant in the vicinity of the cutout 13 is obtainable (crack and the like are prevented) and dust is less likely to be attached.

[Mounting Method]

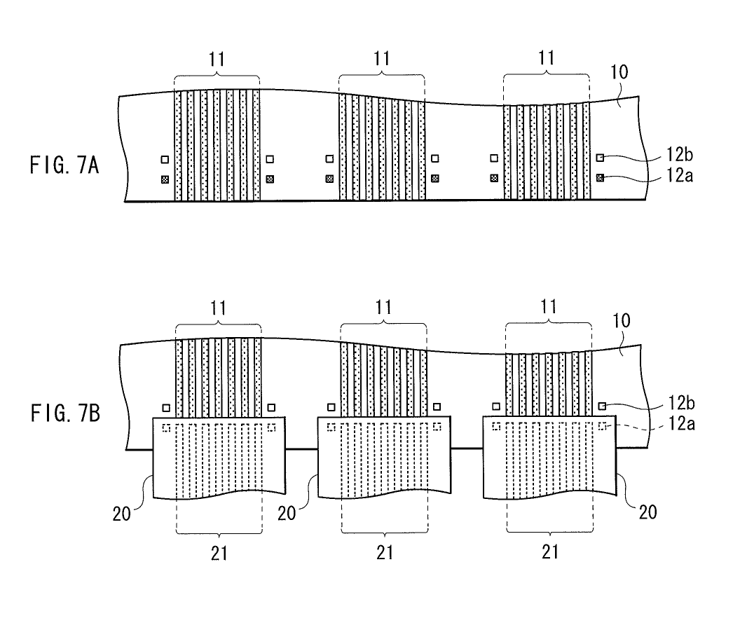

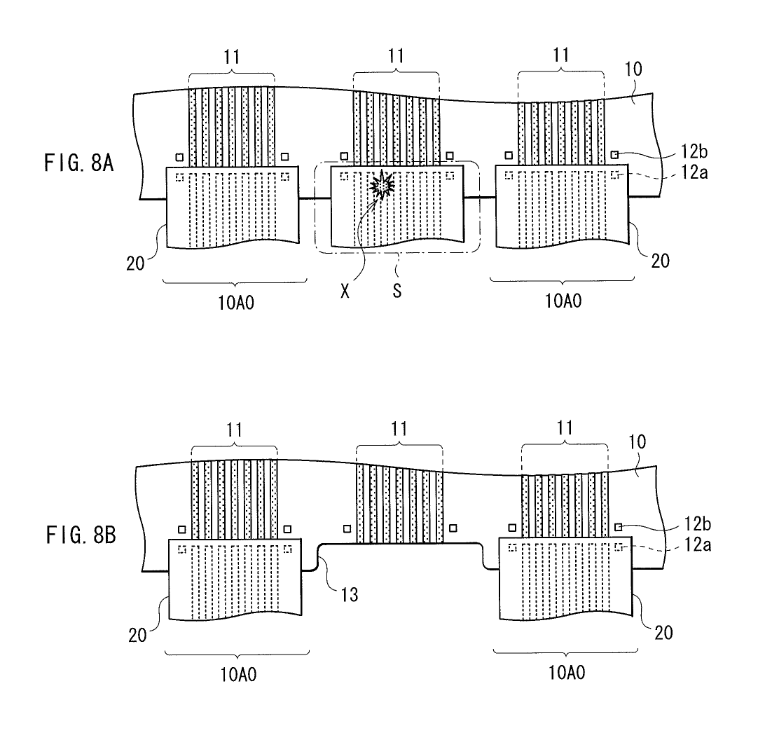

The above-described display module 1 is manufactured through the following mounting processes, for example. FIGS. 7A and 7B and FIGS. 8A and 8B illustrate a mounting method (two-stage mounting) according to the embodiment in a process order. Incidentally, the description is given by taking the configuration in which three bonding portions 10A are arranged as illustrated in FIG. 2, as an example.

First, as illustrated in FIG. 7A, the wiring layers 11 (the wirings 11a and the connection pads 11b) and the alignment marks 12a and 12b are formed. Specifically, the plurality of wiring layers 11 are extended and formed in the periphery of the substrate 10, and the two alignment marks 12a and 12b are formed for each wiring layer 11. The wiring layers 11 and the alignment marks 12a and 12b are collectively formed on the substrate 10 by patterning in a process of forming the device section including the thin film transistor as described above.

Subsequently, as illustrated in FIG. 7B, the FPC bonding (the first bonding) is performed. At this time, for example, the above-described anisotropic conductive adhesive is applied on each of the wiring layers 11 on the substrate 10, and then the FPCs 20 are overlaid and arranged thereon with the adhesive therebetween. After that, alignment is performed for each pair of the wiring layer 11 and the FPC 20, and then the adhesive is cured by thermal compression bonding. At the time of alignment, however, the alignment is performed so that the alignment marks 12a of the alignment marks 12a and 12b on the substrate 10 engage with the alignment marks 22, and the position of the FPC 20 is determined. As a result, the FPCs 20 are bonded to face the wiring layers 11 in the periphery of the substrate 10, and the bonding portions 10A (in detail, the bonding portions 10A0) are formed. Incidentally, in the bonding portions 10A0, the alignment marks 12b are not used and remain on the substrate 10.

After the FPC bonding, it is difficult to ensure the favorable electrical connection between the wiring layer 11 on the substrate 10 and the wiring layer 21 on the FPC 20 in all of the bonding portions 10A, and thus connection failure may occur in a part of the bonding portions. For example, as illustrated in FIG. 8A, the bonding portion where the connection between the wiring layers 11 and 21 is performed without failure (the bonding portion 10A0) and the bonding portion where the connection failure X (displacement, foreign matter contamination, or the like) occur (a target region of repair mounting) in a bonding process are mixedly formed. In particular, when a thermoplastic material such as a plastic material is used for the substrate 10, displacement readily occur due to expansion and contraction of the substrate 10 because the heating process (thermal compression process) is included at the time of bonding as described above. Such connection failure X causes reduction in yield. Thus, the connection failure is desirably eliminated and is a target of repair mounting. Note that the connection failure X is easily detectable using an optical microscope and the like.

Therefore, in the embodiment, in the target region of repair mounting where the connection failure X occurs as described above, only a region S where the FPC 20 is bonded is selectively cut out. Specifically, the region S is cut out by being pressed with a mold corresponding to the shape (a rectangular shape) of the cutout 13 described above. At this time, since the shape (the shape of the mold) of the cutout 13 does not include a bent portion, cracks and the like in the vicinity of the cutout 13 due to stress in pressing, are suppressed, and dust and the like is prevented from accumulating in the mold. The local dividing processing using such a mold is an effective method particularly for the case where a flexible material is used for the substrate 10. Consequently, as illustrated in FIG. 8B, the cutout 13 is formed in the local region of the substrate 10.

Finally, the FPC 20 newly prepared is bonded again to the region where the cutout 13 is formed as described above. At this time, the end of the wiring layer 11 (the connection pad 11b remaining on the substrate 10 after division of the substrate 10) is applied with the above-described anisotropic conductive adhesive, for example, and the FPC 20 is then overlaid and arranged thereon with the adhesive therebetween. After that, alignment is performed, and thermal compression bonding is performed to cure the adhesive. In the second FPC bonding (the repair mounting), however, the alignment is performed so that the alignment marks 12b which have not been cut by the cutout 13 and remains on the substrate 10 engage with the alignment marks 22, thereby determining the position of the FPC 20.

As a result, the bonding portion 10A1 is formed. In this way, in the embodiment, the FPC bonding is allowed to be performed again in the local portion where connection failure occurs in the first FPC bonding.

[Effects]

As described above, in the display module 1 of the embodiment, the plurality of wiring layers 11 extending from the device section toward the periphery is provided on the substrate 10, and the FPC 20 having the wiring layer 21 is bonded to each of the wiring layers 11 in the periphery of the substrate 10. The substrate 10 has the cutout 13 in the region (the bonding portion 10A1) facing at least one FPC 20. In the mounting process, even when connection failure occurs due to displacement or the like, the portion where the connection failure occurs is locally cut out (the cutout is formed), and then rebonding (repair mounting) is allowed to be performed.

Mounting methods according to comparative examples (comparative examples 1 and 2) of the embodiment are described now. In the comparative examples 1 and 2, the repair mounting is performed in the following way.

(Comparative Examples)

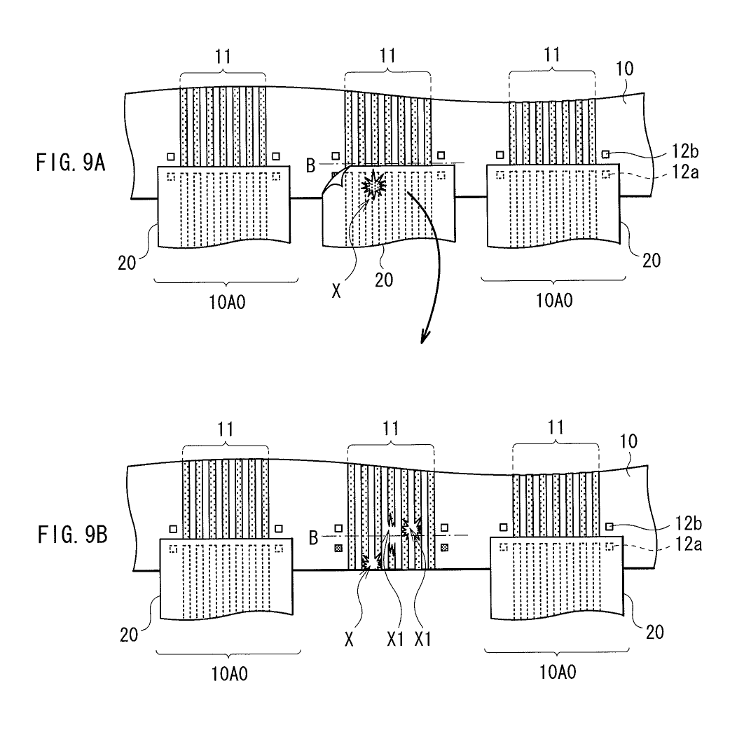

FIGS. 9A and 9B are schematic diagrams for explaining the mounting method of the comparative example 1. The method of the comparative example 1 is a method of mechanically detaching the FPC 20 bonded to the region where the connection failure X occurs as illustrated in FIG. 9A, when the plurality of bonding portions 10A is formed similarly to the embodiment. In the comparative example 1, the substrate 10 is designed to allow two-stage mounting. Then, after the detachment of the FPC 20, the FPC 20 is rebonded. At this time, in the rebonding, the FPC 20 is bonded to a region different from that of the first bonding in the wiring layer 11 with use of the alignment marks 12b provided inner side than the alignment marks 12a used in the first bonding. Thus, repair mounting is achievable.

In the comparative example 1, however, as illustrated in FIG. 9B, mechanical detachment of the FPC 20 may cause additional connection failure X1 (detachment or damage of the wiring layer 11, remaining of the adhesive, and the like), besides the connection failure X in the bonding. In addition, the connection failure X1 may extend to a region inside the wiring layer 11 (closer to the center of the substrate 10) beyond a boundary B between the bonded region and the non-bonded region of the FPC 20 in the first bonding. In such a case, even if the rebonding is newly performed with use of the alignment marks 12b, it is difficult to ensure favorable wiring connection.

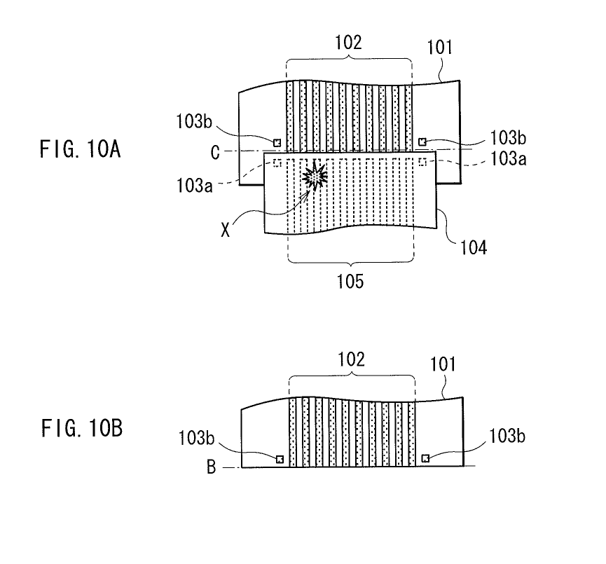

FIGS. 10A and 10B are schematic diagrams for explaining the mounting method of the comparative example 2. The method of the comparative example 2 is a method in the case where one FPC 104 is bonded to a periphery of a substrate 101. In this example, a wiring layer 102 and alignment marks 103a and 103b are formed on the substrate 101 that is formed of a glass substrate, and a wiring layer 105 and alignment marks (not illustrated) are formed on the FPC 104. In the comparative example 2, as illustrated in FIG. 10A, if the connection failure X occurs in the first FPC bonding, the substrate 101 is divided at a boundary C between a bonded region and a non-bonded region of the FPC 104. Therefore, as illustrated in FIG. 10B, one side of the substrate 101 including FPC 104 is cut out. After that, the FPC 104 is rebonded with use of the alignment marks 103b, thereby achieving repair mounting.

In the comparative example 2, unlike the embodiment, a glass is used for the substrate 101, and the number of FPC 104 to be bonded is one. In addition, the substrate 101 is cut out not locally but along one direction. Therefore, even if the portion where the connection failure X occurs is a small portion, it is necessary to cut out the entire wiring layer 102 together with the FPC 104, and to rebond the FPC 104 to the entire region on the one side of the substrate 101 again. In such a method, the region to be bonded is large in rebonding because the mounting area of the FPC 104 is large, and therefore there is a room for improvement in material cost.

In contrast, in the embodiment, as described above, after the first FPC bonding, only the portion where the connection failure occurs is locally cut out (the cutout 13 is formed), and rebonding is performed. Accordingly, unlike the case where the FPC 20 is mechanically detached as the above-described comparative example 1, detachment, damage, and the like of the wiring layer 11 is suppressed in the repair mounting. In addition, unlike the above-described comparative example 2, only the portion where the connection failure occurs is locally cut out, and the FPC 20 is rebonded only in the cutout portion. Therefore, the process is facilitated and there is an advantage in material cost. Consequently, it is possible to improve yield with simple mounting process.

A flexible material such as plastic is desirably used for the substrate 10, and this enables formation of the cutout 13 with ease. In other words, the display module 1 of the embodiment is useful particularly for a flexible display such as an electronic paper display. Incidentally, in the method of the above-described comparative example 2, it is difficult to locally cut out a part of the substrate as the embodiment because the substrate 101 is formed of a glass.

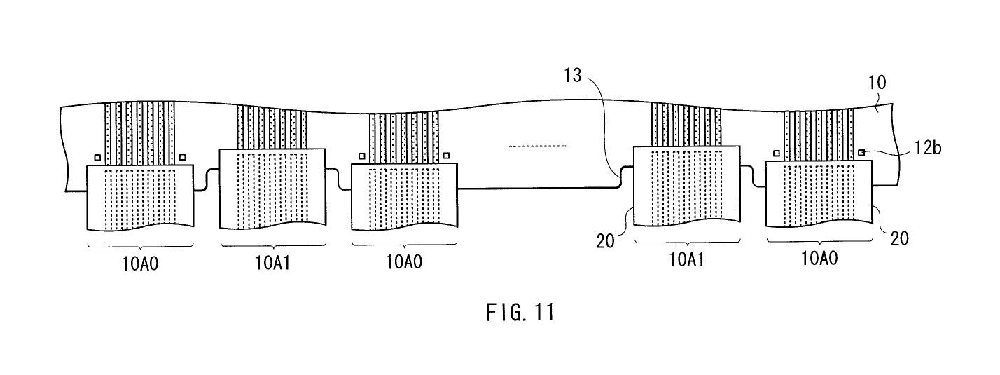

Note that, in the embodiment, one or more of the plurality of bonding portions 10A formed on the substrate 10 are necessary to be the bonding portion 10A1. Specifically, the cutout 13 is necessary to be provided in a region facing one or more FPCs 20, in the periphery of the substrate 10. In addition, when the connection failure X occurs in a plurality of portions in the first FPC bonding, the cutout 13 is formed in each of the portions where the connection failure X occurs, and the repair mounting is respectively performed. FIG. 11 illustrates an example thereof. As illustrated in FIG. 11, the cutout 13 may be formed in each of two or more portions (two or more bonding portions 10A1 may be formed) in the periphery of the substrate 10.

Next, modifications (modifications 1 to 3) of the embodiment will be described. In the following description, like numerals are used to designate substantially like components of the above-described embodiment, and the description thereof is appropriately omitted.

[Modification 1]

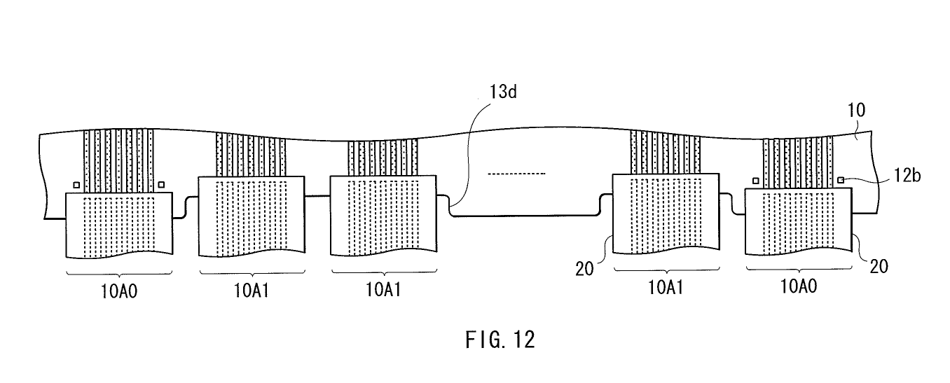

Although the case where the cutout 13 is formed for each bonding portion 10A1 has been described in the embodiment, the cutout 13 may be formed over a plurality of bonding portions 10A1 like the modification 1. For example, as illustrated in FIG. 12, one (common) cutout 13d may be formed with respect to two adjacent bonding portions 10A1. In this case, when the connection failure X occurs in the adjacent pairs of the wiring layer 11 and the FPC 20 in the first FPC bonding, the cutout 13d is formed to divide the two pairs of the wiring layer 11 and the FPC 20 collectively. After that, the FPC bonding is performed again for each wiring layer 11 to achieve repair mounting as described above. In particular, this is effective for the case where the distance between the adjacent wiring layers 11 is narrow.

Incidentally, although the case where the cutout 13d is formed over adjacent two bonding portions 10A1 has been described here, if the connection failure X occurs over three or more pairs which are arranged continuously, or other cases, the cutout 13d may be formed over adjacent three or more bonding portions 10A1. In addition, a cutout formed over the plurality of bonding portions 10A1 and a cutout formed in a region corresponding to one bonding portion 10A1 may be mixedly formed.

[Modification 2]

In addition, in the embodiment, the cutout 13 which has a rectangular shape and further has a curved corner (does not has a bent portion) has been exemplified. Alternatively, the cutout of the disclosure may have other shapes.

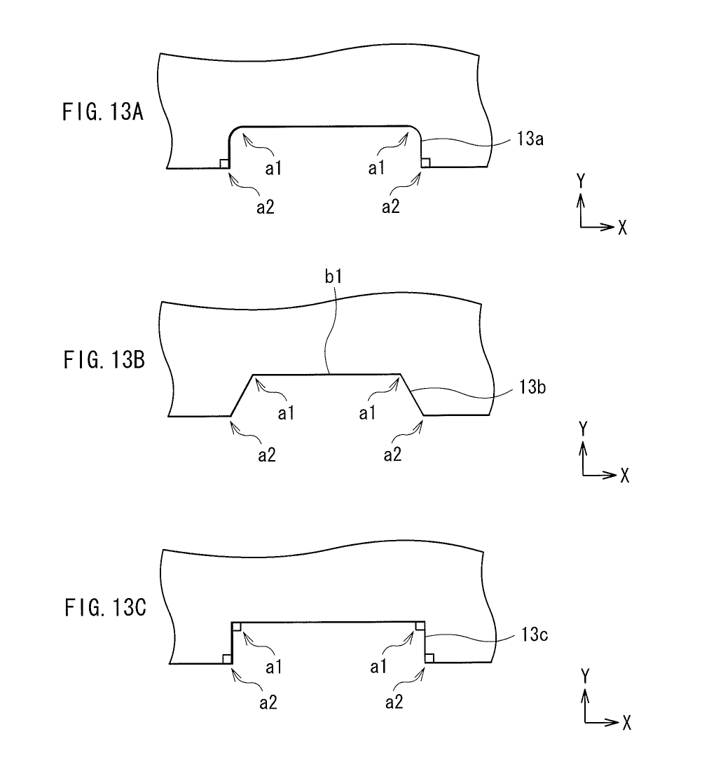

For example, as a cutout 13a illustrated in FIG. 13A, only a corner a1 inside the rectangular shape has a curved shape, and a corner a2 located outside may has a bent shape (for example, a shape bent at a right angle). In addition, as a cutout 13b illustrated in FIG. 13B, an XY plane shape may be a trapezoid with a side b1 inside the substrate 10 as an upper base. Moreover, as a cutout 13c illustrated in FIG. 13C, a rectangular shape in which corners a1 and a2 are bent at a right angle is also available. However, the cutout desirably has a shape without bent portions from a viewpoint of impact resistance and mold management as described above.

[Modification 3]

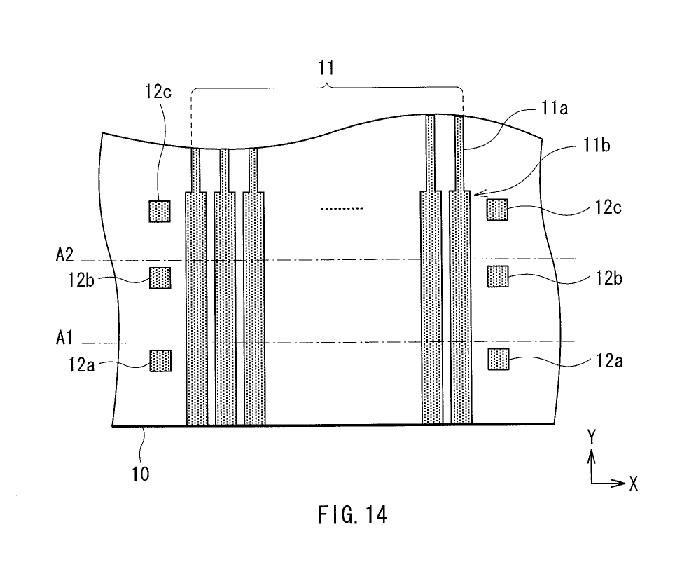

In the embodiment, two-stage mounting in which repair mounting is performed at the second FPC bonding is performed. Alternatively, three-stage mounting may be performed. In this case, each bonding portion is designed so that each bonding portion is allowed to be subjected to FPC bonding up to three times. Specifically, as illustrated in FIG. 14, in the modification 3, another alignment marks (alignment marks 12c) are provided on the inner side than the alignment marks 12b on the substrate 10, in addition to the above-described two alignment marks 12a and 12b. The alignment marks 12a to 12c are disposed with a predetermined distance. In addition, the connection pad 11b is designed to have a width (larger than that of the embodiment) in the Y direction, sufficient for three-stage mounting. Note that the configuration on the FPC 20 side may be similar to that of the embodiment.

In the modification 3, first, when the connection failure X occurs in the first FPC bonding with use of the alignment marks 12a, similarly to the above-described embodiment, an outside portion from the position A1 is locally cut out to form the cutout 13, and then the second FPC bonding is performed with use of the alignment marks 12b. However, actually, favorable wiring connection is not ensured and connection failure X may occur in some cases also in the second FPC bonding. In this case, only in a portion where the connection failure X occurs after the second FPC bonding, an outside portion from a position A2 is locally divided to cut out the end of the wiring layer 11 together with the FPC 20. After that, the third FPC bonding is performed with use of the alignment marks 12c.

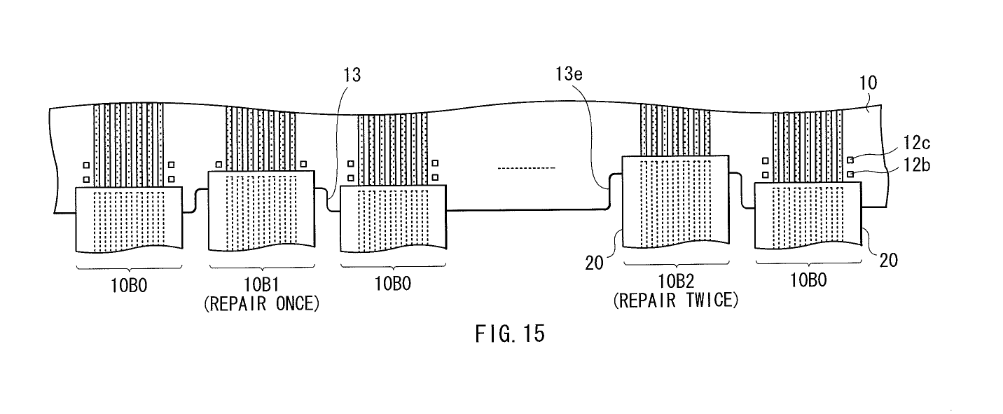

FIG. 15 illustrates an example of a layout of the bonding portions formed through the three-stage mounting of the modification 3. As illustrated in FIG. 15, in the modification 3, a region (a bonding portion 10B0) where favorable wiring connection is obtained by the first FPC bonding, a region (a bonding portion 10B1) where favorable wiring connection is obtained by the second FPC bonding, and a region (a bonding portion 10B2) where favorable wiring connection is obtained by the third FPC bonding are mixedly provided. Note that a cutout 13e formed in a stepwise manner by two times of repair bonding as described above is formed in the bonding portion 10B2. Therefore, the width of the cutout 13e in the Y direction is larger than that of the cutout 13. As described above, cutouts different in shape or size may be mixedly provided.

Note that the number of times of the repair mounting is not limited to once or twice as described above, and may be three or more times (mounting of four or more stages may be performed). In such a case, the number and the location of the alignment marks on the substrate 10, the size of the connection pads, and the like may be appropriately set.

[Application Examples]

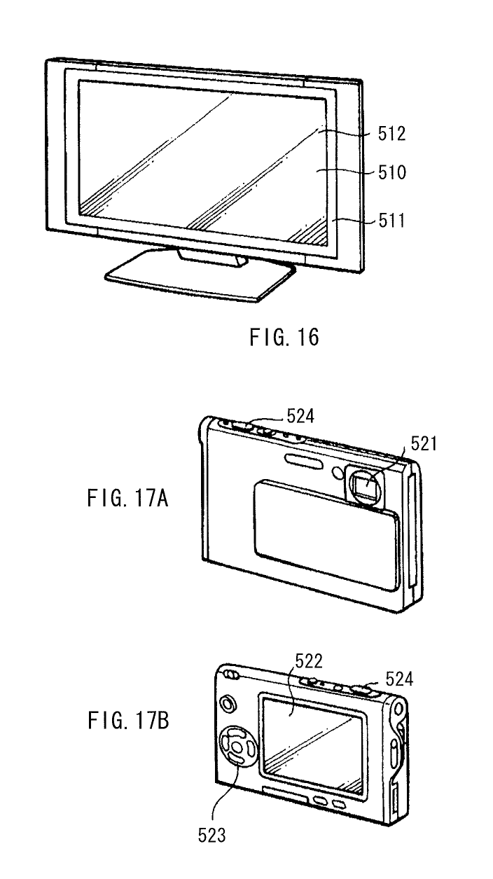

Next, application examples (application examples 1 to 7) of the display module 1 described in the embodiment and the like are described. The display module 1 of the embodiment and the like is allowed to be mounted in electronic apparatuses in various fields, such as a television, a digital camera, a notebook personal computer, mobile terminal devices such as a mobile phone, and a video camera as illustrated in FIG. 16 to FIG. 21B. The display module 1 is applicable to electronic apparatuses in various fields which display an externally input image signal or an internally generated image signal as an image or a picture.

(Application Example 1)

FIG. 16 illustrates an appearance of a television according to an application example 1. The television includes, for example, an image display screen section 510 including a front panel 511 and a filter glass 512.

(Application Example 2)

FIGS. 17A and 17B each illustrate an appearance of a digital camera according to an application example 2. The digital camera includes, for example, a light emitting section 521 for flash light, a display section 522, a menu switch 523, and a shutter button 524.

(Application Example 3)

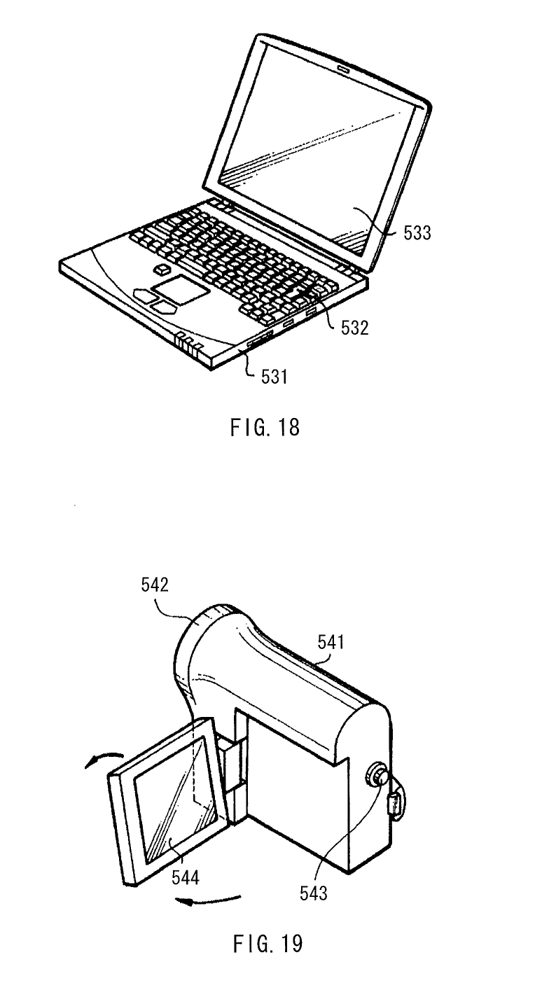

FIG. 18 illustrates an appearance of a notebook personal computer according to an application example 3. The notebook personal computer includes, for example, a main body 531, a keyboard 532 for inputting letters and the like, and a display section 533 displaying an image.

(Application Example 4)

FIG. 19 illustrates an appearance of a video camera according to an application example 4. The video camera includes, for example, a main body section 541, a lens 542 for shooting an object, provided on a front side of the main body section 541, a shooting start-stop switch 543, and a display section 544.

(Application Example 5)

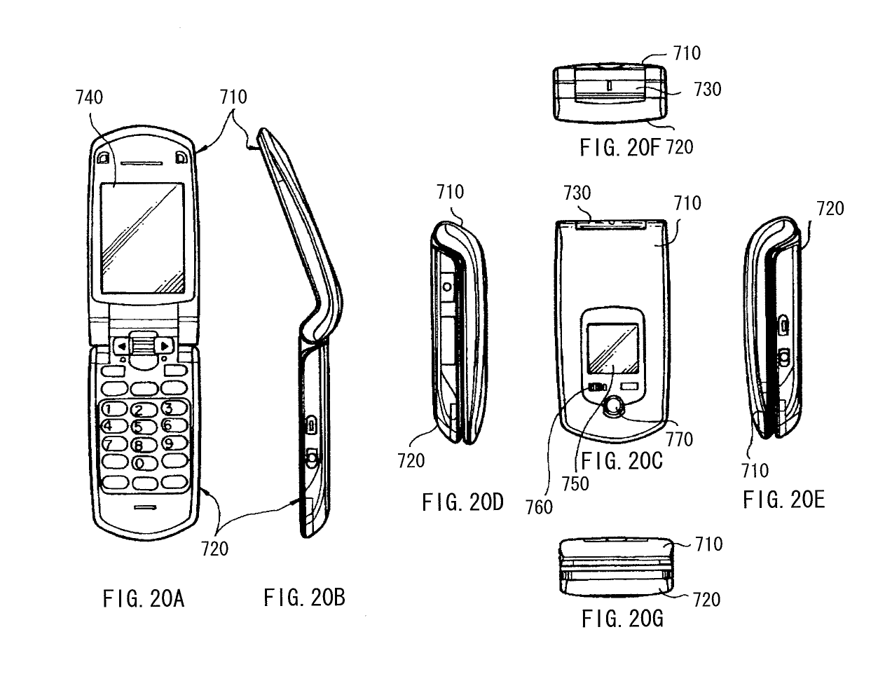

FIGS. 20A to 20G each illustrate an appearance of a mobile phone according to an application example 5. The mobile phone is configured by connecting, for example, an upper housing 710 and a lower housing 720 with a connecting section (a hinge section) 730, and includes a display 740, a sub display 750, a picture light 760, and a camera 770.

(Application Example 6)

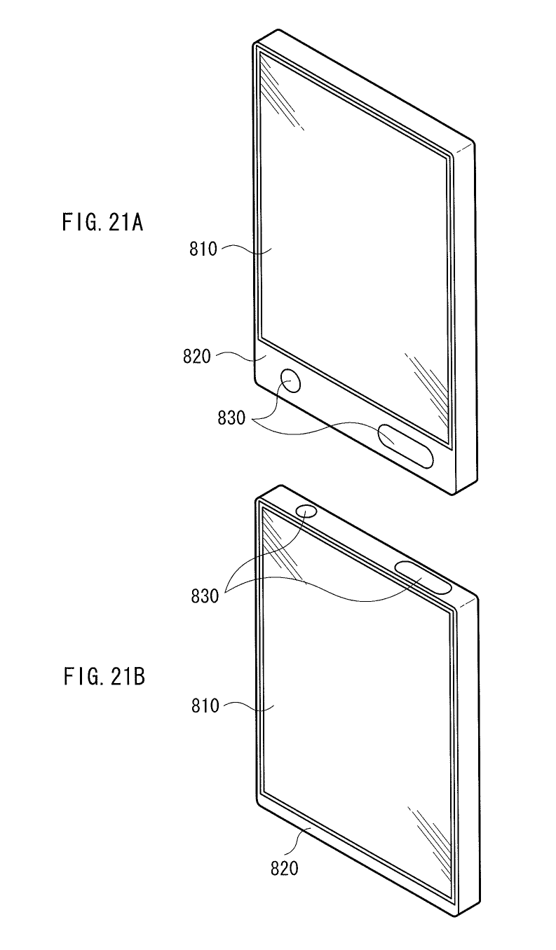

FIGS. 21A and 21B each illustrate an appearance of an electronic book according to an application example 6. The electronic book includes, for example, a display section 810, a non-display section 820, and an operation section 830. The operation section 830 may be formed on the same surface (a front surface) as that of the display section 810 as illustrated in FIG. 21A, or may be formed on a surface (a top surface) different from that of the display section 810 as illustrated in FIG. 21B.

Hereinbefore, although the disclosure has been described with referring to the embodiment, the modifications, and the application examples, the disclosure is not limited to the embodiment and the like, and various modifications may be made. For example, in the above-described embodiment and the like, exemplified is the configuration in which the wirings 11a extending from the device section on the substrate 10 are segmented per a predetermined number of lines, and the predetermined number of segmented wirings 11a is bonded as the wiring layer 11 to the FPC 20. At this time, the plurality of bonding portions may include a bonding portion which is different in the number of wirings, or may include a bonding portion which is different in shape or size of the FPC 20. In addition, when the plurality of cutouts is provided according to the bonding portions, the plurality of cutouts may include a cutout which is different in shape or size.

Moreover, in the embodiment and the like, the configuration in which the wirings 21a and the connection pads 21b of the wiring layer 21 disposed on the FPC 20 are provided on a surface to be bonded to the substrate 10 has been described as an example. Alternatively, the wirings 21a may be drawn to and disposed on an opposite surface of the FPC 20 from the substrate 10 through a through hole, for example. In addition, the wirings 21a may be provided on not only one surface of the FPC 20 but also both surfaces.

Furthermore, in the embodiment and the like, the FPC has been described as the second substrate of the disclosure, as an example. The second substrate does not necessarily have flexibility, and may be configured of a substrate having rigidity.

In addition, in the embodiment and the like, the case where the bonding of the wiring layer 11 and the FPC 20 is performed with use of an anisotropic conductive adhesive (the case of ACF bonding) has been described as an example. However, the bonding method is not limited thereto, and the bonding may be performed with use of, for example, solder.

Moreover, the circuit board of the disclosure is applicable to other semiconductor units such as radio frequency identification (RFID) tags, sensors, and memories, in addition to the display module and the electronic apparatuses as described above. In addition, as the active device, other switching devices, diode devices, and the like may be used, in addition to the thin film transistor as described above.

Note that the disclosure may be configured as follows.

(1) A circuit board including:
a first substrate provided with a device section, the device section including one or a plurality of active devices;
a plurality of first wiring layers each extending from the device section toward a periphery of the first substrate; and
a plurality of second substrates each opposed to and bonded to the first wiring layer at the periphery of the first substrate and each having a second wiring layer, the second wiring layer being electrically connected to each of the first wiring layers, wherein
the first substrate has a cutout in one or more regions each facing one of the plurality of second substrates.

(2) The circuit board according to (1), wherein the first substrate is formed of a material having flexibility.

(3) The circuit board according to (1) or (2), wherein the cutout is provided to divide an end of the first wiring layer.

(4) The circuit board according to (1) to (3), wherein the cutout has a rectangular shape along a substrate surface, and a long side direction of the rectangular shape is along a direction dividing the end of the first wiring layer.

(5) The circuit board according to (4), wherein one or more portions each corresponding to a corner of the rectangular shape each have a curved shape.

(6) The circuit board according to (5), wherein the cutout does not have a bent portion along a substrate surface.

(7) The circuit board according to any one of (1) to (6), wherein the cutout is provided over adjacent two or more regions each facing one of the plurality of second substrates.

(8) The circuit board according to any one of (1) to (7), wherein
the cutout is provided at many positions on the first substrate, and
some of the cutouts are different from the other cutouts in shape or size.

(9) The circuit board according to any one of (1) to (8), wherein one or a plurality of alignment marks is provided for each of the first wiring layers on the first substrate.

(10) The circuit board according to (9), wherein the plurality of alignment marks is arranged from the periphery of the first substrate toward an inner side with a distance when the plurality of alignment marks is provided.

(11) The circuit board according to (10), wherein the plurality of alignment marks includes unused alignment marks.

(12) The circuit board according to any one of (1) to (11), wherein the second substrate is a flexible printed circuit (FPC).

(13) The circuit board according to (1) to (12), wherein an adhesive layer having anisotropic conductivity is provided between the first wiring layer and the second wiring layer of the second substrate.

(14) The circuit board according to any one of (1) to (13), wherein the active device is a thin film transistor (TFT).

(15) A display module including:
a first substrate including a device section and a display section, the device section including one or a plurality of active devices, the display section including a plurality of pixels;
a plurality of first wiring layers each extending from the device section toward a periphery of the first substrate; and
a plurality of second substrates each opposed to and bonded to the first wiring layer in the periphery of the first substrate and each having a second wiring layer, the second wiring layer being electrically connected to each of the first wiring layers, wherein
the first substrate has a cutout in one or more regions each facing one of the plurality of second substrates.

(16) The display module according to (15), wherein the first substrate is formed of a material having flexibility.

(17) An electronic apparatus with a display module, the display module including:
a first substrate including a device section and a display section, the device section including one or a plurality of active devices, the display section including a plurality of pixels;
a plurality of first wiring layers each extending from the device section toward a periphery of the first substrate; and
a plurality of second substrates each opposed to and bonded to the first wiring layer in the periphery of the first substrate, and each having a second wiring layer, the second wiring layer being electrically connected to each of the first wiring layers, wherein
the first substrate has a cutout in one or more regions each facing one of the plurality of second substrates.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A circuit board comprising:
a first substrate provided with a device section, the device section including one or a plurality of active devices;
a plurality of first wiring layers each extending from the device section toward a periphery of the first substrate; and
a plurality of second substrates each opposed to and bonded to the first wiring layer at the periphery of the first substrate and each having a second wiring layer, the second wiring layer being electrically connected to each of the first wiring layers, wherein
the first substrate has a cutout in one or more regions each facing one of the plurality of second substrates.

2. The circuit board according to claim 1, wherein the first substrate is formed of a material having flexibility.

3. The circuit board according to claim 1, wherein the cutout is provided to divide an end of the first wiring layer.

4. The circuit board according to claim 3, wherein the cutout has a rectangular shape along a substrate surface, and a long side direction of the rectangular shape is along a direction dividing the end of the first wiring layer.

5. The circuit board according to claim 4, wherein one or more portions each corresponding to a corner of the rectangular shape each have a curved shape.

6. The circuit board according to claim 5, wherein the cutout does not have a bent portion along a substrate surface.

7. The circuit board according to claim 1, wherein the cutout is provided over adjacent two or more regions each facing one of the plurality of second substrates.

8. The circuit board according to claim 1, wherein
the cutout is provided at many positions on the first substrate, and
some of the cutouts are different from the other cutouts in shape or size.

9. The circuit board according to claim 1, wherein one or a plurality of alignment marks is provided for each of the first wiring layers on the first substrate.

10. The circuit board according to claim 9, wherein the plurality of alignment marks is arranged from the periphery of the first substrate toward an inner side with a distance when the plurality of alignment marks is provided.

11. The circuit board according to claim 10, wherein the plurality of alignment marks includes unused alignment marks.

12. The circuit board according to claim 1, wherein the second substrate is a flexible printed circuit (FPC).

13. The circuit board according to claim 1, wherein an adhesive layer having anisotropic conductivity is provided between the first wiring layer and the second wiring layer of the second substrate.

14. The circuit board according to claim 1, wherein the active device is a thin film transistor (TFT).

15. A display module comprising:
a first substrate including a device section and a display section, the device section including one or a plurality of active devices, the display section including a plurality of pixels;
a plurality of first wiring layers each extending from the device section toward a periphery of the first substrate; and
a plurality of second substrates each opposed to and bonded to the first wiring layer in the periphery of the first substrate and each having a second wiring layer, the second wiring layer being electrically connected to each of the first wiring layers, wherein
the first substrate has a cutout in one or more regions each facing one of the plurality of second substrates.

16. The display module according to claim 15, wherein the first substrate is formed of a material having flexibility.

17. An electronic apparatus with a display module, the display module comprising:
a first substrate including a device section and a display section, the device section including one or a plurality of active devices, the display section including a plurality of pixels;
a plurality of first wiring layers each extending from the device section toward a periphery of the first substrate; and
a plurality of second substrates each opposed to and bonded to the first wiring layer in the periphery of the first substrate, and each having a second wiring layer, the second wiring layer being electrically connected to each of the first wiring layers, wherein
the first substrate has a cutout in one or more regions each facing one of the plurality of second substrates.
